(19) United States
(12) Patent Application Publication
(10) Pub. No.: US 2026/0181910 A1
(43) Pub. Date: Jun. 25, 2026

(54) MAGNETIC TUNNEL JUNCTION WITH DOUBLE FIXED LAYERS, MAGNETIC MEMORY CHIP, AND MANUFACTURING METHOD THEREOF

(71) Applicants: YANGTZE DELTA GRADUATE SCHOOL OF BEIJING INSTITUTE OF TECHNOLOGY (JIAXING), JIAXING (CN); BEIJING INSTITUTE OF TECHNOLOGY, BEIJING (CN)

(72) Inventors: SHUJUN YE, BEIJING (CN); KOICHI NISHIOKA, JIAXING (CN)

(73) Assignees: YANGTZE DELTA GRADUATE SCHOOL OF BEIJING INSTITUTE OF TECHNOLOGY (JIAXING), JIAXING (CN); BEIJING INSTITUTE OF TECHNOLOGY, BEIJING (CN)

(21) Appl. No.: 19/006,591

(22) Filed: Dec. 31, 2024

Related U.S. Application Data
(63) Continuation of application No. PCT/CN2024/140726, filed on Dec. 19, 2024.

(51) Int. Cl. H10B 61/00; H10N 50/01; H10N 50/10; H10N 50/85

(52) U.S. Cl. CPC H10B 61/10; H10N 50/01; H10N 50/10; H10N 50/85

(57) ABSTRACT

The present disclosure relates to a magnetic tunnel junction with double fixed layers, a magnetic memory chip, and a manufacturing method thereof. The present disclosure provides a magnetic tunnel junction with double fixed layers, a magnetic memory chip, and a manufacturing method thereof, including a structure of a bottom fixed layer formed by three layers of ferromagnetic thin film structures coupled in an anti-parallel manner, and then, from the perspective of the coupling magnetic field of the bottom fixed layer to the free layer, a thickness and a material of each layer of the ferromagnetic thin film structure of the above-mentioned structure are provided, and, on the basis of the bottom fixed layer, a structure of the top fixed layer is further provided. The present disclosure provides a magnetic tunnel junction with double fixed layers, a magnetic memory chip, and a manufacturing method thereof.

### TECHNICAL FIELD

The present disclosure relates to the field of magnetic memory chip in an integrated circuit, and specifically relates to a magnetic tunnel junction with double fixed layers, a magnetic memory chip, and a manufacturing method thereof.

### BACKGROUND ART

A magnetic tunnel junction (MTJ) is made up of one tunneling layer of insulator oxide (generally MgO) sandwiched by two ferromagnetic (ferromagnet) thin film structures. A spin direction (also referred to as a direction of magnetization) of one of the ferromagnetic thin film structures (fixed layer) of the MTJ is fixed, the spin direction of another one of the ferromagnetic thin film structures (free layer) is changed, two different resistance states can be generated, which can be used for the storage and the read and write of numerical information “0” and “1”, and thereby can be used for a magnetic memory chip (MRAM, also referred to as magnetic random access memory or random read access memory).

An important topic of MRAM based on spin transfer torque (STT) MTJ is that the writing electrical voltage of the MTJ device is relatively high, causing damage to an insulator of the tunneling layer. In the writing information process, the free layer receives magnetic moment from conduction electrons whose spins were polarized after going through the fixed layer and thereby the free layer magnetically reverses. The greater the difference in the quantities of upward and downward spins polarized during going through the fixed layer, the writing current from anti-parallel state to parallel state (Free layer magnetic moment is parallel to that of fixed layer in anti-parallel state and free layer magnetic moment is anti-parallel to that of fixed layer in anti-parallel state.) is decreased. However, the writing current from the parallel state to the anti-parallel is increased on the contrary. Therefore, the Structure of STT-MTJ Having Structure of Double Fixed Layers and MRAM Thereof and Manufacturing Method Thereof (Chinese patent: CN2024106136795) is proposed. In addition, the structure of STT-MTJ with double fixed layers and MRAM thereof and the manufacturing method are further proposed from the perspectives of the difficulty of manufacturing method of a top fixed layer, coercivity, and a coupling magnetic field of the fixed layer to the free layer (Chinese patent: CN2024110822877).

The above-mentioned proposal did not simultaneously discuss the impact of the top and bottom fixed layers of the double fixed layers on the free layer, and specifically did not specify the structure of the bottom fixed layer. The present disclosure proposes a structure of the top fixed layer and bottom fixed layer of the magnetic tunnel junction with double fixed layers, as well as a structure of MRAM composed thereof and a preparation method thereof, from the perspective of a coupling between the top fixed layer thin film structure (referred to as the top fixed layer, Top or Top Pin for short) and the bottom fixed layer thin film structure (referred to as the bottom fixed layer, Bottom or Btm or Btm Pin for short) on the free layer thin film structure (referred to as the free layer, Free layer or FL for short), and from the perspective of the direction of magnetization of the prepared magnetic tunnel junction with double fixed layers. When designing the MRAM bottom fixed layer according to the usual method, many problems may arise, as explained below:

FIG. 7(A) shows structures of a fixed layer (left) of MTJ of a single ferromagnetic thin film structure and the fixed layer (right) of MTJ composed of two ferromagnetic thin film structures coupled in an anti-parallel manner, wherein coupling layers between the ferromagnetic thin film structures and the free layer are omitted. For the fixed layer of a single ferromagnetic thin film structure, the fixed layer exerts two types of forces on the free layer, namely magneto-static field and exchange coupling. Therefore, the fixed layer has a relatively large force on the free layer, which is not conducive to information writing in the free layer (i.e. spin reversal). In the two ferromagnetic thin film structures coupled in anti-parallel manner on the right, the magnetic moment (also known as magnetic momentum or magnetization) of the ferromagnetic Pin 1, which is usually closer to the free layer, is smaller than that of Pin 2, which is farther away from the free layer. Pin 1 will generate a magneto-static field and exchange coupling between adjacent free layers. When the magnetic moment of Pin 1 is small, both of these effects are relatively small, especially the exchange coupling can be almost negligible. Although the magnetic moment far away from Pin 2 is relatively large, due to its remote distance from the free layer, the magneto-static field and exchange coupling forces generated by the adjacent free layer are also relatively small. FIG. 7(B) is a schematic diagram of a hysteresis loop when the fixed layers of the MTJ of the two structures in FIG. 7(A) are magnetically coupled to the free layer. Although the effect of exchange coupling on the free layer is negligible, the magneto-static fields of Pin 1 and Pin 2 generate a coupling magnetic field (H_{bias}) on the free layer. For the structure in FIG. 7(A), assuming that the free layer is a CoFeB alloy thin film with a thickness of x nanometers, x is usually less than 3 nanometers. Ferromagnetic thin film structure in the fixed layer is generally a multi-layer repetitive structure of a composite structure of Co and Pt, and is designated as (Co/Pt)z; z is L in the fixed layer of MTJ of the single ferromagnetic thin film structure in FIG. 7(A), and the z of Pin 1 and z of Pin2 are respectively M and N in the fixed layers of MTJ of the two ferromagnetic thin film structures in anti-parallel coupling. Since both Pin 1 and Pin 2 are the same body structure (Co/Pt)z, the times of repetitions of the body structure is positively related to the magnetic moments of Pin 1 and Pin 2. As previously mentioned, the magnetic moment of Pin 1 is less than that of Pin 2, and M<N. Under the identical situation of body structure, through thickness adjustment of the ferromagnetic thin film structure or the adjustment of the times of repetitions z of the body structure (Co/Pt)z, the major parameters of magnetic performance (including saturation magnetic moment, coercivity, and a coupling of the fixed layer to the free layer) can be restricted, thus resulting in limitations related to thickness (in this case, quantity of layers) in the claims. Using the commonly used Co/Pt structure with Co of a thickness of less than 0.8 nanometer and Pt of a thickness of less than 0.5 nanometer, FIG. 7(C) compares the coupling magnetic fields of the fixed layers to the free layer when z is an integer L less than 9 in the fixed layer of MTJ of a single ferromagnetic thin film structure (Pin 1), and when the z of Pin 1 and z of Pin 2 are M (<4) and N (<6), respectively, and L=M+N in the fixed layers of MTJ of the two ferromagnetic thin film structures coupled in anti-parallel manner. As shown in FIG. 7(C), within a diameter range of 10 nanometers to 80 nanometers of the MTJ, the coupling magnetic field generated by the fixed layers of the MTJ of the two ferromagnetic thin film structures coupled in an anti-parallel manner on the free layer is significantly reduced compared to the fixed layer composed of the single ferromagnetic thin film structure. The smaller the coupling magnetic field (also referred to as coupling bias), the smaller the energy consumption required to invert the free layer.

On the basis of the above-described contents, the influence of top fixed layer is further considered. FIG. 8(A) is a schematic diagram of a structure of an MTJ with double fixed layers, where both a top fixed layer and a bottom fixed layer are composed of two ferromagnetic thin film structures coupled in an anti-parallel manner, and a magnetic moment of the ferromagnetic thin film structure, close to the free layer, in the two fixed layers is relatively small. The purpose of using a smaller magnetic moment structure in the ferromagnetic thin film structure, close to the free layer, of the fixed layers is to reduce the coupling magnetic field of the fixed layer to the free layer. However, for the structure in FIG. 8(A), when an external magnetic field is removed after excitation with a magnetic field of 10 kOe, as shown in FIG. 8(B), the spin direction of the ferromagnetic thin film structure, close to the free layer, in the top fixed layer is parallel to that of the ferromagnetic thin film structure, close to the free layer, in the bottom fixed layer. At this time, information writing cannot be performed using the STT-MTJ with double fixed layers proposed previously (Chinese patent: CN2024106136795), and therefore the structure cannot be applied.

Both the top fixed layer and the bottom fixed layer of the MTJ in FIG. 9 are composed of two ferromagnetic thin film structures coupled in an anti-parallel manner, and the magnetic moment of the ferromagnetic thin film structure, close to the free layer, in the bottom fixed layer is relatively large, while the magnetic moment of the ferromagnetic thin film structure, close to the free layer, in the top fixed layer is relatively small. At this point, the spin direction of the ferromagnetic thin film structure, close to the free layer, in the top fixed layer is anti-parallel to the spin direction of the ferromagnetic thin film structure, close to the free layer, in the bottom fixed layer. Therefore, the coupling magnetic field between the top and bottom fixed layers and the free layer will be cancelled out, and a smaller coupling magnetic field is expected to be generated, which can theoretically be used.

FIG. 10(A) is a schematic diagram of a structure of portions of the bottom fixed layer and the free layer of the MTJ with double fixed layers, wherein the bottom fixed layer in FIG. 9 is composed of two ferromagnetic thin film structures coupled in an anti-parallel manner, and the magnetic moment of the ferromagnetic thin film structure, close to the free layer, in the bottom fixed layer is relatively large. When the free layer is 2.3 nanometers and a distance between the free layer and Pin 1 and a distance between Pin 1 and Pin 2 are both 0.9 nanometer, as shown in FIG. 10(B), Pin 1 and Pin 2 with different thicknesses are set. The coupling magnetic fields between the fixed layer and the free layer under conditions of different diameters of MTJ are shown in FIG. 10(C). The coupling magnetic fields under all three conditions are greater than 1000 Oe for STT-MTJ with a diameter of no more than 20 nanometers that may be widely applied; at a diameter of 40 nanometers, the coupled magnetic fields under all three conditions are greater than 750 Oe. The MTJ with double fixed layers can offset a part of the coupling magnetic field generated by the top and bottom fixed layers when applied, and thus it is considered that the coupling magnetic field generated by any fixed layer of the double fixed layers shall be less than 750 Oe for large-scale application. When the MTJ mentioned above is no more than 40 nanometers, the coupling magnetic field generated by the bottom fixed layer is greater than 750 Oe, making it difficult for this structure to be applied on a large scale.

In order to solve the above-mentioned problems, the present disclosure first proposes a magnetic tunnel junction with double fixed layers, a magnetic memory chip, and a manufacturing method thereof, including a structure of a bottom fixed layer formed by three layers of ferromagnetic thin film structures coupled in an anti-parallel manner, and then, from the perspective of the coupling magnetic field of the bottom fixed layer to the free layer, a thickness and a material of each layer of the ferromagnetic thin film structure of the above-mentioned structure are proposed, and, on the basis of the bottom fixed layer, a structure of the top fixed layer is further proposed. At the same time, proposals are made for the MTJ with double fixed layers of the structure proposed above and the manufacturing method thereof.

### SUMMARY OF THE INVENTION

On the basis of the above-mentioned background and problem, the present disclosure proposes a magnetic tunnel junction with double fixed layers, a magnetic memory chip, and a manufacturing method thereof. Details are provided as follows:

In a magnetic tunnel junction with double fixed layers, the magnetic tunnel junction is composed of a bottom fixed layer thin film structure, a bottom tunneling layer oxide thin film structure, a free layer thin film structure, a top tunneling layer oxide thin film structure and a top fixed layer thin film structure from near to far from a substrate; the bottom fixed layer thin film structure is composed of, from near to far from the free layer, a bottom first ferromagnetic thin film structure with a spin direction opposite to a spin direction of a ferromagnetic thin film structure, closest to the free layer, in the top fixed layer thin film structure, a bottom first anti-parallel coupling thin film structure, a bottom second ferromagnetic thin film structure with a spin direction opposite to the spin direction of the bottom first ferromagnetic thin film structure, a bottom second anti-parallel coupling thin film structure, and a bottom third ferromagnetic thin film structure with a spin direction opposite to the spin direction of the bottom second ferromagnetic thin film structure; and a thickness D1 of the bottom first ferromagnetic thin film structure, a thickness D2 of the bottom second ferromagnetic thin film structure and a thickness D3 of the bottom third ferromagnetic thin film structure satisfy a relationship of D1<D2 and D1<D3 and 0.29<D2/(D1+D2+D3)<0.5.

The following supplementary description is made on the above-mentioned contents: in the present proposal, the top fixed layer thin film structure is also composed of a plurality of ferromagnetic thin film structures, but the ferromagnetic thin film structure, nearest to the free layer, of the top fixed layer thin film structure and the ferromagnetic thin film structure, nearest to the free layer, of the bottom fixed layer thin film structure must have opposite spin directions, which is the basis for enabling the MTJ with double fixed layers satisfying the proposal of the present disclosure to write STT information. All thin film structures in the present specification refer to structures composed of one or more layers of thin films. The fixed layer thin film structure refers to one layer or multiple layers of thin film structures with the main property of ferromagnetism as the fixed layer of the magnetic tunnel junction. The bottom tunneling layer oxide thin film structure refers to one layer or multiple layers of thin film structures that are predominantly oxide as the tunneling layer of the magnetic tunnel junction. The free layer thin film structure refers to one layer or multiple layers of thin film structures that are predominantly ferromagnetic thin films as the free layer of the magnetic tunnel junction. That is, a film structure refers to one layer or multiple layers of thin film structures that are dominated by a certain primary property or primary material. The above-mentioned fixed layer thin film structure may also be referred to as a fixed layer; similarly, a free layer thin film structure or the like may also be referred to simply as a free layer. Since the main compositions of the bottom first ferromagnetic thin film structure, the bottom second ferromagnetic thin film structure, and the bottom third ferromagnetic thin film structure are the same in the present proposal, the present proposal adjusts the main parameters of the magnetic properties (including a saturation magnetic moment, a coercivity, and a coupling of the fixed layer to the free layer, etc.) through a thickness of the ferromagnetic thin film structure, thereby resulting in the above-mentioned thickness-related limitation, which is described in detail in the embodiments.

According to the magnetic tunnel junction with double fixed layers provided in the present disclosure, the bottom first ferromagnetic thin film structure is composed of a cobalt metal thin film and a cobalt-iron-boron alloy thin film successively deposited on an integer n of repetitive structure of two layers of thin films of a cobalt metal thin film and a platinum thin film from near to far from the substrate, and the integer n is 0 or 1; the bottom second ferromagnetic thin film structure is composed of a cobalt metal thin film deposited on an integer m of repetitive structure(s) of two layers of thin films of a cobalt metal thin film and a platinum thin film from near to far from the substrate; and the bottom third ferromagnetic thin film structure is composed of a cobalt metal thin film deposited on an integer/of repetitive structure(s) of two layers of thin films of a cobalt metal thin film and a platinum thin film from near to far from the substrate.

The following supplementary description is made on the above-mentioned contents: an integer x of repetitive structures of two layers of thin films of the cobalt metal (Co) thin film and the platinum (Pt) thin film are usually denoted as (Co/Pt)x, which are x(x=n, m, l) repetitive structures of the structure with Co below and Pt above. By analogy, other structures can be presumed. The cobalt-iron-boron alloy of the bottom first ferromagnetic thin film structure is an essential part for the formation of magnesium oxide in the following tunneling layer. From the results of some experiments and simulations, the smaller the thickness of the bottom first ferromagnetic thin film structure, the smaller the coupling magnetic field generated by the bottom fixed layer to the free layer. The above-mentioned relationship of n, m and/is also derived from the above-mentioned thickness relationship.

According to the present disclosure, there is provided a magnetic tunnel junction with double fixed layers, including the following structures that:

(1.1) the top fixed layer thin film structure is composed of a top first ferromagnetic thin film structure, a top first anti-parallel coupling thin film structure, a top second ferromagnetic thin film structure with a spin direction opposite to a spin direction of the top first ferromagnetic thin film structure, a top first oxide coupling thin film structure, and a top third ferromagnetic thin film structure having a same spin direction as the top second ferromagnetic thin film structure from near to far from the substrate; a top of the top fixed layer thin film structure is composed of a magnesium oxide thin film for improving magnetic perpendicular anisotropy.

(1.2) the top fixed layer thin film structure is composed of a top first ferromagnetic thin film structure, a top first anti-parallel coupling thin film structure, a top second ferromagnetic thin film structure with a spin direction opposite to a spin direction of the top first ferromagnetic thin film structure, a top first oxide coupling thin film structure, a top third ferromagnetic thin film structure having a same spin direction as the top second ferromagnetic thin film structure, a top second oxide coupling thin film structure, and a top fourth ferromagnetic thin film structure having a same spin direction as the top third ferromagnetic thin film structure from near to far from the substrate; a top of the top fixed layer thin film structure is composed of a magnesium oxide thin film structure for improving magnetic perpendicular anisotropy.

(1.3) the top fixed layer thin film structure is composed of a top first ferromagnetic thin film structure, a top first oxide coupling thin film structure, a top second ferromagnetic thin film structure having a same spin direction as the top first ferromagnetic thin film structure, a top first anti-parallel coupling thin film structure, a top third ferromagnetic thin film structure with a spin direction opposite to a spin direction of the top second ferromagnetic thin film structure, a top second oxide coupling thin film structure, and a top fourth ferromagnetic thin film structure having a same spin direction as the top third ferromagnetic thin film structure from near to far from the substrate; a top of the top fixed layer thin film structure is composed of an antiferromagnetic thin film structure for spin pinning.

(1.4) the top fixed layer thin film structure is composed of a top first ferromagnetic thin film structure, a top first oxide coupling thin film structure, a top second ferromagnetic thin film structure having a same spin direction as the top first ferromagnetic thin film structure, a top first anti-parallel coupling thin film structure, a top third ferromagnetic thin film structure with a spin direction opposite to a spin direction of the top second ferromagnetic thin film structure, a top second oxide coupling thin film structure, a top fourth ferromagnetic thin film structure having a same spin direction as the top third ferromagnetic thin film structure, a top third oxide coupling thin film structure, and a top fifth ferromagnetic thin film structure having a same spin direction as the top fourth ferromagnetic thin film structure from near to far from the substrate; a top of the top fixed layer thin film structure is composed of a magnesium oxide thin film structure for improving magnetic perpendicular anisotropy.

(1.5) the top fixed layer thin film structure is composed of a top first ferromagnetic thin film structure, a top first anti-parallel coupling thin film structure, a top second ferromagnetic thin film structure with a spin direction opposite to a spin direction of the top first ferromagnetic thin film structure, a top first oxide coupling thin film structure, a top third ferromagnetic thin film structure having a same spin direction as the top second ferromagnetic thin film structure, a top second anti-parallel coupling thin film structure, and a top fourth ferromagnetic thin film structure with a spin direction opposite to a spin direction of the top third ferromagnetic thin film structure from near to far from the substrate; a top of the top fixed layer thin film structure is composed of an antiferromagnetic thin film structure for spin pinning.

The following supplementary explanations are given for the above-mentioned five new structures of MTJ: the above-mentioned five structures are proposals for the top fixed layer after the structure of the bottom fixed layer is determined, considering how the spin directions of ferromagnetism of each layer of the bottom fixed layer and the top fixed layer to be arranged in a predetermined manner after the magnetic tunnel junction is formed, and considering that the coupling magnetic field of the top fixed layer to the free layer is reduced as much as possible.

According to the magnetic tunnel junction with double fixed layers provided by the present disclosure, the material of the anti-parallel coupling thin film structure generally uses any one of metal ruthenium or metal iridium; the oxide coupling thin film structure is composed of any one of magnesium oxide containing, in addition to boron element, any one element of iron and cobalt and having a thickness greater than that of the magnesium oxide of the tunneling layer, an oxide of iron, and an oxide containing iron and cobalt.

According to the magnetic tunnel junction with double fixed layers provided by the present disclosure, the antiferromagnetic thin film structure at least contains any one antiferromagnet of a manganese platinum alloy or a manganese iridium alloy.

The following supplementary description is made on the above-mentioned contents: the spin directions of the multiple layers of ferromagnetic thin film structures in the present proposal require the formation of an anti-parallel spin direction alignment by anti-parallel coupling, while oxide coupling is used to form a parallel spin direction alignment.

In another aspect, the present disclosure also provides a method for manufacturing a magnetic memory chip of a magnetic tunnel junction with double fixed layers prepared on the basis of the magnetic tunnel junction with double fixed layers, including the steps of:
(2.1) preparing a peripheral circuit of the magnetic memory chip on the substrate;
(2.2) performing preparation of a bottom electrode of the magnetic tunnel junction on a metal connection layer of the peripheral circuit;
(2.3) preparing a connection layer between the bottom electrode and the bottom fixed layer thin film structure;
(2.4) preparing the bottom first ferromagnetic thin film structure, the bottom first anti-parallel coupling thin film structure, the bottom second ferromagnetic thin film structure, the bottom second anti-parallel coupling thin film structure, and the bottom third ferromagnetic thin film structure of the bottom fixed layer thin film structure;
(2.5) preparing the bottom tunneling layer oxide thin film structure;
(2.6) preparing the free layer thin film structure;
(2.7) preparing the top tunneling layer oxide thin film structure;
(2.8) preparing the top fixed layer thin film structure;
(2.9) preparing a top cover protective layer;
(2.10) patterning a thin film to form a device of the magnetic memory chip; and
(2.11) performing connection and packaging of the device to form a chip.

The following supplementary description is made on the above-mentioned contents: the practical fabrication of MRAM chips is complex. The above-mentioned steps are only the main steps associated with the structure of the present proposal in the formation and fabrication of MRAM chips. There may be many details between, before, and after the steps, which are omitted for reasons of brevity but do not affect the claimed characteristic steps of the present disclosure.

According to the method for manufacturing a magnetic memory chip of a magnetic tunnel junction with double fixed layers provided in the present disclosure, any of the steps of preparing the top fixed layer thin film structure, preparing a top cover protective layer, and patterning a thin film to form a device of the magnetic memory chip is followed by a step of returning to an external field-free environment after being magnetized by a magnetic field of not less than 1 tesla.

The following supplementary description is made on the above-mentioned contents: annealing magnetization is an important fabrication step for MRAM chips. With respect to the characteristic structure proposed in the present disclosure, the alignment of the spin directions of various ferromagnetic thin film structure can be achieved by the above-described annealing magnetization process.

The conventional STT-MTJ with a single fixed layer uses a ferromagnetic thin film with high spin polarizability as a fixed layer to decrease the information writing current in one direction while increasing the information writing current in the other direction. STT-MTJ using double fixed layers is expected to solve the above-mentioned problem. In particular, the present disclosure proposes a structure of top and bottom double fixed layers and a manufacturing method thereof from the perspectives of the coupling magnetic field of the fixed layer to the free layer and the control of the spin alignment of the various components of the fixed layer, which is expected to reduce the information writing current in two directions of the STT-MTJ, thus achieving a stable magnetic memory MRAM chip.

### BRIEF DESCRIPTION OF THE DRAWINGS

FIG. 1 is a schematic diagram of a basic structure of a magnetic tunnel junction MTJ device with double fixed layers having a structure of a characteristic bottom fixed layer, which is one embodiment of the present disclosure.

FIGS. 2-6 are schematic diagrams of five embodiments of the present disclosure, namely, five different structures of top fixed layers of the MTJ with double fixed layers based on the structure of characteristic bottom fixed layer of FIG. 1.

FIG. 7(A) shows structures of a fixed layer of MTJ of a single ferromagnetic thin film structure and a fixed layer of MTJ of two ferromagnetic thin film structures coupled in an anti-parallel manner, wherein coupling layers among the ferromagnetic thin film structures and the free layer are omitted. (B) shows a schematic diagram of hysteresis loop when the fixed layer of MTJ is magnetically coupled to the free layer; and (C) shows a comparison result of coupling fields generated on the free layer by fixed layers of two types of MTJs in (A) at different diameters of the MTJ device.

FIG. 8(A) is a schematic diagram of a structure of an MTJ with double fixed layers, where both a top fixed layer and a bottom fixed layer are composed of two ferromagnetic thin film structures coupled in an anti-parallel manner, and a magnetic moment of the ferromagnetic thin film structure, close to the free layer, in the two fixed layers is relatively small; and (B) shows a schematic diagram of an arrangement of spin directions of various ferromagnetic thin film structures in (A) under a magnetic field of 10 kOe and with removal of an external magnetic field.

FIG. 9 is a schematic diagram of an arrangement of spin directions of the structure of MTJ with double fixed layers and various ferromagnetic thin film structures after excitation at 10 kOe and removal of the external magnetic field when both the top fixed layer and the bottom fixed layer of the structure are composed of two ferromagnetic thin film structures coupled in an anti-parallel manner, and the magnetic moment of the ferromagnetic thin film structure, close to the free layer, in the bottom fixed layer is relatively large, while the magnetic moment of the ferromagnetic thin film structure, close to the free layer, in the top fixed layer is relatively small.

FIG. 10(A) is a schematic diagram of a structure of portions of the bottom fixed layer and the free layer of the MTJ with double fixed layers, wherein the bottom fixed layer in FIG. 9 is composed of two ferromagnetic thin film structures coupled in an anti-parallel manner, and the magnetic moment of the ferromagnetic thin film structure, close to the free layer, in the bottom fixed layer is relatively large; (B) shows three different thickness combinations of the two ferromagnetic thin film structures that constitute the bottom fixed layer in (A); and (C) shows a result of a coupling magnetic field of the bottom fixed layer to the free layer which varies with a diameter of the MTJ device for the three different thickness combinations in (B).

FIG. 11 is one of the embodiments of the present disclosure, and is a schematic diagram of an arrangement of spin directions of the structure of MTJ with double fixed layers and various ferromagnetic thin film structures after excitation at 10 kOe and removal of the external magnetic field when the top fixed layer of the structure is composed of two ferromagnetic thin film structures coupled in an anti-parallel manner, the bottom fixed layer is composed of three ferromagnetic thin film structures coupled in an anti-parallel manner, and the magnetic moments of the ferromagnetic thin film structures, close to the free layer, in the bottom fixed layer and the top fixed layer are both relatively small.

FIG. 12 is one of the embodiments of the present disclosure, (A) shows a schematic diagram of a structure of portions of the bottom fixed layer and the free layer of the MTJ with double fixed layers, wherein the bottom fixed layer in FIG. 11 is composed of three ferromagnetic thin film structures coupled in an anti-parallel manner, and the magnetic moment of the ferromagnetic thin film structure, close to the free layer, in the bottom fixed layer is relatively small; (B) shows eight different thickness combinations of the three ferromagnetic thin film structures that constitute the bottom fixed layer in (A); and (C) shows a result of a coupling magnetic field of the bottom fixed layer to the free layer which varies with a diameter of the MTJ device for the eight different thickness combinations in (B).

FIG. 13 shows variation of the coupling magnetic field of the bottom fixed layer to the free layer when a ratio of D2/(D1+D2+D3) changes at a diameter of the MTJ device of 20 nanometers, with thicknesses of three layers of ferromagnetic thin film structures, which constitute the fixed layer, of the bottom fixed layer of the structure in FIG. 12, from one close to the free layer to one remote from the free layer, being D1, D2, and D3, respectively.

FIG. 14 is one of the embodiments of the present disclosure, (A) shows a schematic diagram of a structure of portions of the bottom fixed layer and the free layer of the MTJ with double fixed layers, wherein the bottom fixed layer in FIG. 11 is composed of three ferromagnetic thin film structures coupled in an anti-parallel manner, and the magnetic moment of the ferromagnetic thin film structure, close to the free layer, in the bottom fixed layer is relatively small; (B) shows six different thickness combinations of the three ferromagnetic thin film structures that constitute the bottom fixed layer in (A); and (C) shows a result of a coupling magnetic field of the bottom fixed layer to the free layer which varies with a diameter of the MTJ device for the six different thickness combinations in (B).

FIG. 15 shows a comparison of the magnetic coupling fields generated by the top fixed layers of the MTJ with double fixed layers to the free layers for the structures of five embodiments in FIGS. 2-6 under different diameters of devices.

### DETAILED DESCRIPTION OF THE INVENTION

The present disclosure is illustrated in combination with the figures and exemplary implementations.

### Embodiment 1

FIG. 11 shows one embodiment of the present disclosure, which is a characteristic structure of an MTJ with double fixed layers according to the present disclosure, The top fixed layer of the structure is composed of two ferromagnetic thin film structures coupled in an anti-parallel manner (top first and second ferromagnetic thin film structures), and the bottom fixed layer is composed of three ferromagnetic thin film structures coupled in an anti-parallel manner (bottom first, second, and third ferromagnetic thin film structures, the magnetic moments being m1, m2, and m3, respectively), and m2<m1+m3. The spin directions of all ferromagnetic thin film structures (with magnetic moments of m1, m2, m3, m4, and m5, respectively) in FIG. 11 are aligned downwards when a 10 kOe downward magnetic field is applied. With the external magnetic field removed, m5 is larger than m4, m5 remains downward, and m4 and m5 form an anti-parallel relationship. m1 and m2 are in anti-parallel relationship with each other, while m2 and m3 are in anti-parallel relationship with each other. Because of the relationship m2<m1+m3 described above, m1 and m3 remain spinning downwards, while m2 spins upwards because of their anti-parallel relationship. Thus the bottom first ferromagnetic thin film structure m1 and the top first ferromagnetic thin film structure m4 can form an anti-parallel relationship, enabling information writing of the STT-MTJ with double fixed layers, as previously described.

FIG. 12(A) shows an embodiment of the bottom structure in the structure of FIG. 11. A thickness of the free layer FL is d5, while distances between each pair of the free layer FL, the bottom first ferromagnetic thin film structure (Pin 1), the bottom second ferromagnetic thin film structure (Pin 2), and the bottom third ferromagnetic thin film structure (Pin 3) are successively d6, d7, and d8, respectively, in units of nanometers. The composition of various components is as follows from bottom to top:

$$[ Co ( d 1 ) / Pt ( d 2 ) ] \times n / Co ( d 3 ) / CoFeb ( d 4 ) \qquad Pin1$$

$$[ Co ( d 1 ) / Pt ( d 2 ) ] \times m / Co ( d 3 ) \qquad Pin 2$$

$$[ Co ( d 1 ) / Pt ( d 2 ) ] \times l / Co ( d 3 ) \qquad Pin3$$

The d1, d2, d3, and d4 in parentheses are in units of nanometers. n, m, and/are integers representing a number repetitions of [Co (d1)/Pt (d2)]. The film thickness can be adjusted by adjusting the values of these integers. When d1<0.8, d2<0.5, d3<0.85, d4<2, d5<3, d6<1.2, d7<1.2, and d7<1.2 (all units for d1 to d8 are nanometers), keeping a magnetic moment Ms of FL<1.5 tesla, and a magnetic moment Ms of the bottom fixed layer<1.4 tesla, the coupling magnetic fields of the bottom fixed layer to the free layer are obtained according to the combined structure with 8 different thicknesses listed in FIG. 12(B) and are compared in FIG. 12(C). It was found that when n is 0 and m is greater than 2 (Case #s-3 to Case #s-8), the coupling magnetic field from the bottom fixed layer to the free layer is less than 750 Oe over a comparative diameter range of 10 nm to 80 nm. Therefore, the application condition of the MTJ with double fixed layers is satisfied; when n is 0 and m is equal to 2, i.e. Case #s-2, coupling magnetic field of the bottom fixed layer to the free layer is greater than 750 Oe over the comparative diameter range of 10 nm to 80 nm. In particular, a Ref. coupling magnetic field with n equal to 7 is greater than 1500 Oe, which cannot be applied according to the previous analysis.

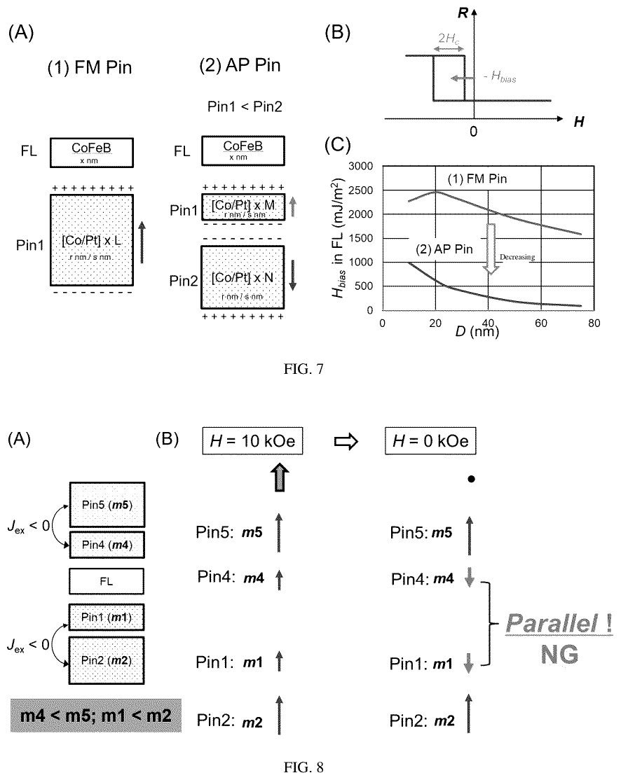

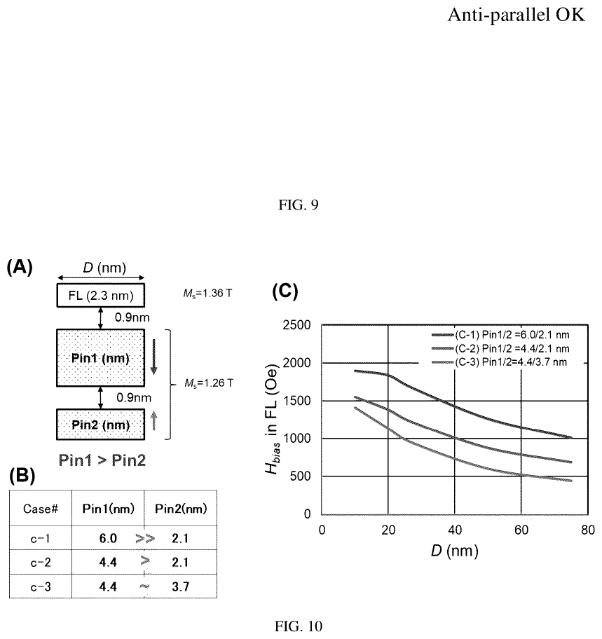

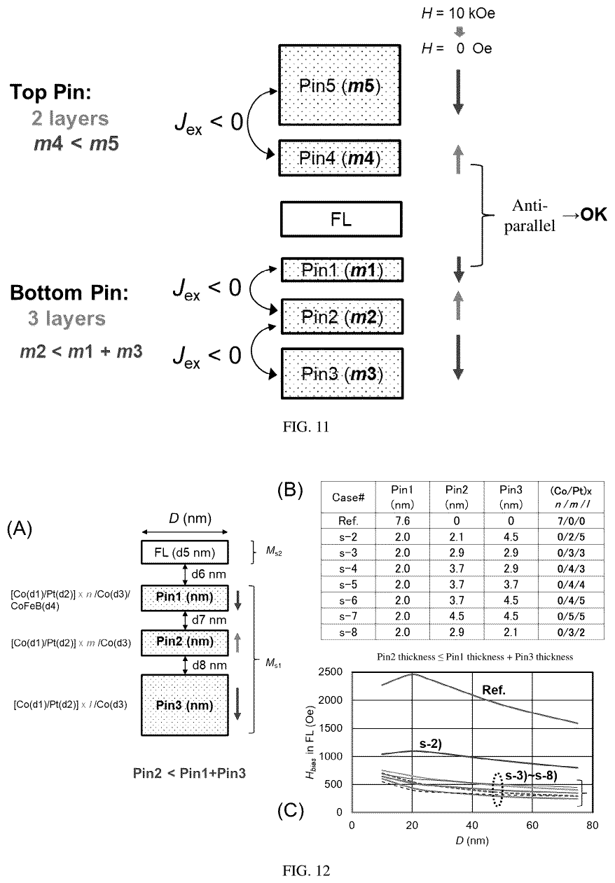

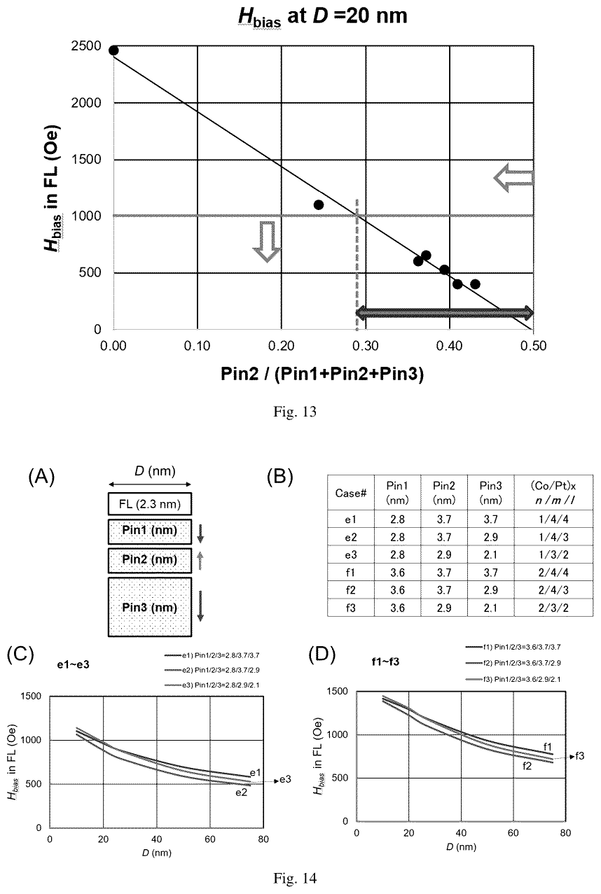

FIG. 13 shows a ratio of a film thickness of Pin2 (abbreviated as Pin2) to a sum of a film thickness of Pin1 (abbreviated as Pin1), a film thickness of Pin2 and a film thickness of Pin3 (abbreviated as Pin3) at 20 nm for the MTJs with double fixed layers of various structures in FIG. 12(B), which is denoted as Pin2/(Pin1+Pin2+Pin3). Taking the ratio as the abscissa, and the coupling magnetic field values of the bottom fixed layer to the free layer of various structures as the ordinate, it is found that the Pin2/(Pin1+Pin2+Pin3) is linear with the coupling magnetic field, and it is found that if the coupling magnetic field is less than 750 Oe, the Pin2/(Pin1+Pin2+Pin3) needs to be greater than 0.35. When Pin2/(Pin1+Pin2+Pin3) is 0.5, the coupling magnetic field is 0, which is ideal. However, the previous (embodiment of FIG. 11) spin direction alignment requires m2<m1+m3, i.e. Pin2/(Pin1+Pin2+Pin3) needs to be less than 0.5. Considering the 20 nm for comparison here, and considering that the previous results (FIG. 7(C), FIG. 10(C), and FIG. 12(C)) show that the smaller the diameter, the larger the coupling magnetic field, the proposal of the present disclosure considers the need to satisfy the coupling magnetic field of less than 1000 Oe. Therefore, the following conditions need to be satisfied: 0.29<Pin2/(Pin1+Pin2+Pin3)<0.50. It should be noted that since FIG. 13 mainly uses an alloy of Co and Pt, the number of times of repetitions of the two layers of thin films of the thickness or the body structure (Co/Pt) is positively correlated with magnetic characteristics such as magnetic moment (m).

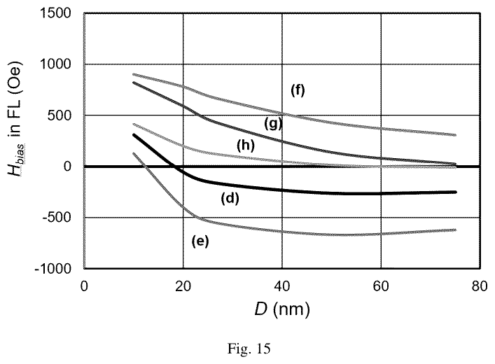

FIG. 14(A) is also based on the same characteristic structure of FIG. 12, but the thicknesses of the bottom first ferromagnetic thin film structure (Pin 1), the bottom second ferromagnetic thin film structure (Pin 2), and the bottom third ferromagnetic thin film structure (Pin 3) are adjusted. The n value of [Co (d1)/Pt (d2)] n of the bottom first ferromagnetic thin film structure is adjusted to 1 and 2, and the specific thickness can be seen in FIG. 14(B). When n is 1 and 2, the coupling magnetic fields of the fixed layer to the free layer obtained under the condition of MTJ with different diameters are shown in FIG. 14(C) and FIG. 14(D), respectively. When n=1, the diameter is more than 30 nm, which ensures that the coupling magnetic field of the fixed layer to the free layer is less than 750 Oe. However, when n=2, the diameter is more than 60 nm, which ensures that the coupling magnetic field of the fixed layer to the free layer is less than 750 Oe. Because STT-MTJ based MRAM is replacing SRAM and DRAM applications, device size (high integration density) is an important measurement. In view of practical applications, MRAM is generally required to be no more than 40 nm for a most promising large-scale substitution of DRAM and SRAM. That is, when n=1, the structure is expected to be applied on a large scale, and when n=2, it is difficult for the structure to be applied on a large scale. Considering FIG. 12(C), in the structure proposed by the present disclosure, it is necessary to satisfy n<2, preferably n=0. In an embodiment of the present proposal, n<2, corresponding to a thickness of the bottom first ferromagnetic thin film structure (Pin 1 or m1) of less than 2.8 nm.

### Embodiment 2

FIG. 1 is a schematic diagram of a basic structure of a magnetic tunnel junction MTJ device with double fixed layers having a structure of a characteristic bottom fixed layer, which is one embodiment of the present disclosure. 7 is the free layer, and 1 and 2 are a bottom tunneling layer oxide thin film structure and a top tunneling layer oxide thin film structure, respectively. 81, 82, and 83 are bottom first, second and third ferromagnetic thin film structures respectively, and 31 and 32 are bottom first and second anti-parallel coupling thin film structures respectively. 81 and 82 are coupled in an anti-parallel manner via 31 and 82 and 83 are coupled in an anti-parallel manner via 32. 81, 82, 83, 31, and 32 constitute a characteristic structure of the bottom fixed layer thin film structure of a structure of the double fixed layers according to the proposal of the present disclosure. 9 is a top fixed layer thin film structure.

After excitation, the structure enables a spin direction of the first ferromagnetic thin film structure of the top fixed layer thin film structure to be opposite toa spin direction of the bottom first ferromagnetic thin film structure, and the spin direction of the bottom first ferromagnetic thin film structure to be opposite to a spin direction of the second ferromagnetic thin film structure, and the spin direction of the second ferromagnetic thin film structure to be opposite to a spin direction of the third ferromagnetic thin film structure. In FIG. 1, the spin direction of the bottom first ferromagnetic thin film structure is downward, while tops of the bottom second ferromagnetic thin film structure and the bottom third ferromagnetic thin film structure are upward, downward, and upward, respectively. It is reversed if the spin direction of the bottom first ferromagnetic thin film structure is upward, and the directions of the other ferromagnetic thin film structures are also changed. As stated above, in the present disclosure, the top fixed layer thin film structure is also composed of multiple layers of ferromagnetic thin film structures, and the top fixed layer is not defined in detail in FIG. 1, so that although the spin direction of the first ferromagnetic thin film structure of the top fixed layer thin film structure is opposite to the spin direction of the bottom first ferromagnetic thin film structure, the spin direction of the top fixed layer thin film structure as a whole cannot be specified in FIG. 1.

### Embodiment 3

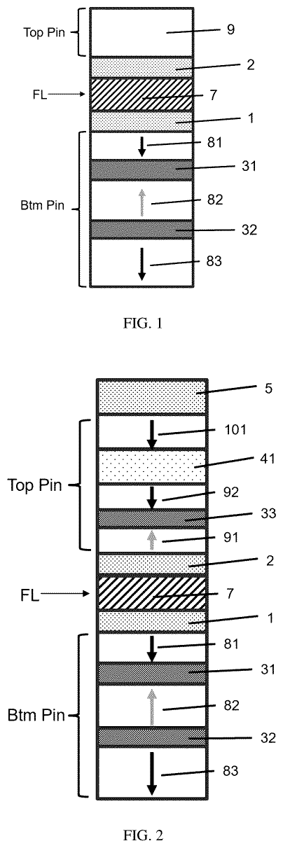

FIGS. 2-6 are schematic diagrams of five embodiments of the present disclosure, namely, five different structures of top fixed layers of the MTJ with double fixed layers based on the structure of characteristic bottom fixed layer of FIG. 1.

In FIGS. 2, 91 and 92 are top first and top second ferromagnetic thin film structures coupled in an anti-parallel manner via a top first anti-parallel coupling thin film structure 33. 101 is a top third ferromagnetic thin film structure, and is coupled in a parallel manner with the top second ferromagnetic thin film structure 92 via the top first oxide coupling thin film structure 41. 5 is a magnesium oxide thin film structure for improving magnetic perpendicular anisotropy. The aforementioned 91, 33, 92, 41, and 101 constitute the top fixed layer thin film structure of FIG. 2. By removing the applied magnetic field after excitation, the spin directions of the top first, second and third ferromagnetic thin film structures are respectively upward, downward and downward when the spin direction of the bottom first ferromagnetic thin film structure is downward. Conversely, when the spin direction of the bottom first ferromagnetic thin film structure is upward, the spin directions of the top first, second and third ferromagnetic thin film structures are downward, upward and upward, respectively.

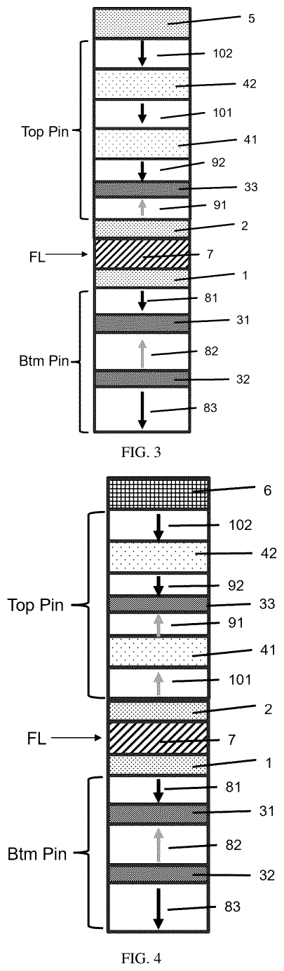

In FIG. 3, on top of the top third ferromagnetic thin film structure 101 of FIG. 2, a top fourth ferromagnetic thin film structure with a spin direction parallel to a spin direction of the top third ferromagnetic thin film structure 101 is formed by the top second oxide coupling thin film structure 42, followed by formation of a magnesium oxide thin film structure 5 for improving magnetic perpendicular anisotropy. The aforementioned 91, 33, 92, 41, 101, 42, and 102 constitute the top fixed layer thin film structure of FIG. 3. By removing the external magnetic field after the excitation, when the spin direction of the bottom first ferromagnetic thin film structure is downward, the spin directions of the top first, second, third and fourth ferromagnetic thin film structures are respectively upward, downward, downward and downward; conversely, the corresponding relationship is also satisfied.

In FIG. 4, the top first ferromagnetic thin film structure 101 and the top second ferromagnetic thin film structure 91 are coupled in a parallel manner via the top first oxide coupling thin film structure 41. In turn, 91 forms an anti-parallel coupling with the top third ferromagnetic thin film structure 92 via the top first anti-parallel coupling thin film structure 33. 92 is in turn coupled in a parallel manner with the top fourth ferromagnetic thin film structure 102 via the top second oxide coupling thin film structure 42. An antiferromagnetic thin film structure 6 for spin pinning is further formed above 102. The aforementioned 101, 41, 91, 33, 92, 42, and 102 constitute the top fixed layer thin film structure of FIG. 4. By removing the external magnetic field after the excitation, when the spin direction of the bottom first ferromagnetic thin film structure is downward, the spin directions of the top first, second, third and fourth ferromagnetic thin film structures are respectively upward, upward, downward and downward; conversely, the corresponding relationship is also satisfied.

In FIG. 5, a top third oxide coupling thin film structure 43 is further formed above 102 of FIG. 4 to be coupled in a parallel manner with a top fifth ferromagnetic thin film structure 103. A magnesium oxide thin film structure 5 for subsequently improving magnetic perpendicular anisotropy is formed above 103. The above-mentioned 101, 41, 91, 33, 92, 42, 102, 43, 103 constitute the top fixed layer thin film structure of FIG. 5. By removing the external magnetic field after the excitation, when the spin direction of the bottom first ferromagnetic thin film structure is downward, the spin directions of the top first, second, third, fourth and fifth ferromagnetic thin film structures are respectively upward, upward, downward, downward and downward; conversely, the corresponding relationship is also satisfied.

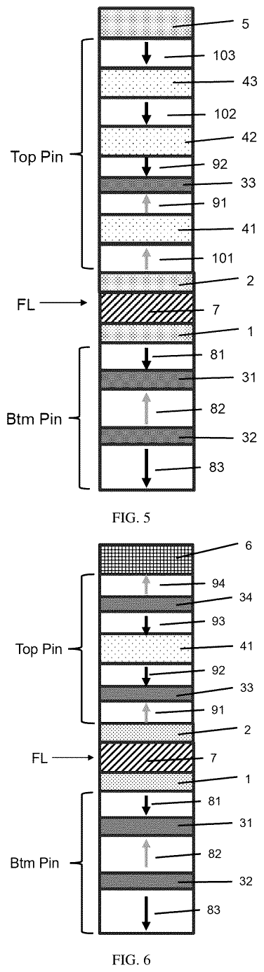

In FIGS. 6, 91 and 92 are top first and top second ferromagnetic thin film structures coupled in an anti-parallel manner via a top first anti-parallel coupling thin film structure 33. 93 is a top third ferromagnetic thin film structure, and is coupled in a parallel manner with the top second ferromagnetic thin film structure 92 via the top first oxide coupling thin film structure 41. The top fourth ferromagnetic thin film structure 94 and the top third ferromagnetic thin film structure 93 are coupled in an anti-parallel manner via the top second anti-parallel coupling thin film structure 34. An antiferromagnetic thin film structure 6 for spin pinning is further formed above 94. The aforementioned 91, 33, 92, 41, 93, 34, and 94 constitute the top fixed layer thin film structure of FIG. 6. By removing the external magnetic field after excitation, when the spin direction of the bottom first ferromagnetic thin film structure is downward, the spin directions of the top first, second, third and fourth ferromagnetic thin film structures are respectively upward, downward, downward and upward; conversely, the corresponding relationship is also satisfied.

FIG. 15 shows a comparison of the magnetic coupling fields generated by the top fixed layers of the MTJ with double fixed layers to the free layers for the structures of five embodiments in FIGS. 2-6 under different diameters of devices. (d), (e), (f), (g) and (h) respectively correspond to FIG. 2, FIG. 3, FIG. 4, FIG. 5 and FIG. 6. It can be seen that all the five structures can satisfy that the coupling magnetic field of the top fixed layer to the free layer is less than 750 Oe at a diameter greater than 20 nm. Since the MTJ is actually composed of a multilayer nanoscale film, the preparation conditions of the film somewhat affect the relevant properties. The present proposal therefore defines solely the coupling magnetic fields of the top and bottom fixed layers to the free layer, respectively.

This proposal is expected to greatly reduce the energy consumption of information writing in an STT-MTJ-based MRAM chip and greatly increase its durability, so as to realize the large-scale application of MRAM instead of DRAM and SRAM.

All the embodiments described above only express certain implementations of the present disclosure, the description is concrete, but they can not be understood as restriction to the scope of the disclosure patent. It should be noted that a person skilled in the art would have been able to make several variations and improvements without departing from the concepts of the present disclosure, and these variations and improvements are also considered to be within the scope of protection of the present disclosure. Accordingly, the scope of protection sought in the present disclosure is as set forth in the claims below.

1. A magnetic tunnel junction with double fixed layers, characterized in that the magnetic tunnel junction is composed of a bottom fixed layer thin film structure, a bottom tunneling layer oxide thin film structure, a free layer thin film structure, a top tunneling layer oxide thin film structure and a top fixed layer thin film structure from near to far from a substrate; the bottom fixed layer thin film structure is composed of, from near to far from the free layer, a bottom first ferromagnetic thin film structure with a spin direction opposite to a spin direction of a ferromagnetic thin film structure, closest to the free layer, in the top fixed layer thin film structure, a bottom first anti-parallel coupling thin film structure, a bottom second ferromagnetic thin film structure with a spin direction opposite to the spin direction of the bottom first ferromagnetic thin film structure, a bottom second anti-parallel coupling thin film structure, and a bottom third ferromagnetic thin film structure with a spin direction opposite to the spin direction of the bottom second ferromagnetic thin film structure; and a thickness D1 of the bottom first ferromagnetic thin film structure, a thickness D2 of the bottom second ferromagnetic thin film structure and a thickness D3 of the bottom third ferromagnetic thin film structure satisfy a relationship of D1<D2 and D1<D3 and 0.29<D2/(D1+D2+D3)<0.5.

2. The magnetic tunnel junction with double fixed layers according to claim 1, characterized in that the bottom first ferromagnetic thin film structure is composed of a cobalt metal thin film and a cobalt-iron-boron alloy thin film successively deposited on an integer n of repetitive structure of two layers of thin films of a cobalt metal thin film and a platinum thin film from near to far from the substrate, and the integer n is 0 or 1; the bottom second ferromagnetic thin film structure is composed of a cobalt metal thin film deposited on an integer m of repetitive structure(s) of two layers of thin films of a cobalt metal thin film and a platinum thin film from near to far from the substrate; and the bottom third ferromagnetic thin film structure is composed of a cobalt metal thin film deposited on an integer 1 of repetitive structure(s) of two layers of thin films of a cobalt metal thin film and a platinum thin film from near to far from the substrate.

3. The magnetic tunnel junction with double fixed layers according to claim 2, characterized in that the top fixed layer thin film structure is composed of a top first ferromagnetic thin film structure, a top first anti-parallel coupling thin film structure, a top second ferromagnetic thin film structure with a spin direction opposite to a spin direction of the top first ferromagnetic thin film structure, a top first oxide coupling thin film structure, and a top third ferromagnetic thin film structure having a same spin direction as the top second ferromagnetic thin film structure from near to far from the substrate; a top of the top fixed layer thin film structure is composed of a magnesium oxide thin film for improving magnetic perpendicular anisotropy; a material of the anti-parallel coupling thin film structure uses any one of metal ruthenium or metal iridium; and the oxide coupling thin film structure is composed of any one of magnesium oxide containing, in addition to boron element, any one element of iron and cobalt and having a thickness greater than that of magnesium oxide of the tunneling layer, an oxide of iron, and an oxide containing iron and cobalt.

4. The magnetic tunnel junction with double fixed layers according to claim 2, characterized in that the top fixed layer thin film structure is composed of a top first ferromagnetic thin film structure, a top first anti-parallel coupling thin film structure, a top second ferromagnetic thin film structure with a spin direction opposite to a spin direction of the top first ferromagnetic thin film structure, a top first oxide coupling thin film structure, a top third ferromagnetic thin film structure having a same spin direction as the top second ferromagnetic thin film structure, a top second oxide coupling thin film structure, and a top fourth ferromagnetic thin film structure having a same spin direction as the top third ferromagnetic thin film structure from near to far from the substrate; a top of the top fixed layer thin film structure is composed of a magnesium oxide thin film structure for improving magnetic perpendicular anisotropy; a material of the anti-parallel coupling thin film structure uses any one of metal ruthenium or metal iridium; and the oxide coupling thin film structure is composed of any one of magnesium oxide containing, in addition to boron element, any one element of iron and cobalt and having a thickness greater than that of magnesium oxide of the tunneling layer, an oxide of iron, and an oxide containing iron and cobalt.

5. The magnetic tunnel junction with double fixed layers according to claim 2, characterized in that the top fixed layer thin film structure is composed of a top first ferromagnetic thin film structure, a top first oxide coupling thin film structure, a top second ferromagnetic thin film structure having a same spin direction as the top first ferromagnetic thin film structure, a top first anti-parallel coupling thin film structure, a top third ferromagnetic thin film structure with a spin direction opposite to a spin direction of the top second ferromagnetic thin film structure, a top second oxide coupling thin film structure, and a top fourth ferromagnetic thin film structure having a same spin direction as the top third ferromagnetic thin film structure from near to far from the substrate; a top of the top fixed layer thin film structure is composed of an antiferromagnetic thin film structure for spin pinning; a material of the anti-parallel coupling thin film structure uses any one of metal ruthenium or metal iridium; the oxide coupling thin film structure is composed of any one of magnesium oxide containing, in addition to boron element, any one element of iron and cobalt and having a thickness greater than that of magnesium oxide of the tunneling layer, an oxide of iron, and an oxide containing iron and cobalt; and the antiferromagnetic thin film structure contains at least any one antiferromagnet of a manganese platinum alloy or a manganese iridium alloy.

6. The magnetic tunnel junction with double fixed layers according to claim 2, characterized in that the top fixed layer thin film structure is composed of a top first ferromagnetic thin film structure, a top first oxide coupling thin film structure, a top second ferromagnetic thin film structure having a same spin direction as the top first ferromagnetic thin film structure, a top first anti-parallel coupling thin film structure, a top third ferromagnetic thin film structure with a spin direction opposite to a spin direction of the top second ferromagnetic thin film structure, a top second oxide coupling thin film structure, a top fourth ferromagnetic thin film structure having a same spin direction as the top third ferromagnetic thin film structure, a top third oxide coupling thin film structure, and a top fifth ferromagnetic thin film structure having a same spin direction as the top fourth ferromagnetic thin film structure from near to far from the substrate; a top of the top fixed layer thin film structure is composed of a magnesium oxide thin film structure for improving magnetic perpendicular anisotropy; a material of the anti-parallel coupling thin film structure uses any one of metal ruthenium or metal iridium; and the oxide coupling thin film structure is composed of any one of magnesium oxide containing, in addition to boron element, any one element of iron and cobalt and having a thickness greater than that of magnesium oxide of the tunneling layer, an oxide of iron, and an oxide containing iron and cobalt.

7. The magnetic tunnel junction with double fixed layers according to claim 2, characterized in that the top fixed layer thin film structure is composed of a top first ferromagnetic thin film structure, a top first anti-parallel coupling thin film structure, a top second ferromagnetic thin film structure with a spin direction opposite to a spin direction of the top first ferromagnetic thin film structure, a top first oxide coupling thin film structure, a top third ferromagnetic thin film structure having a same spin direction as the top second ferromagnetic thin film structure, a top second anti-parallel coupling thin film structure, and a top fourth ferromagnetic thin film structure with a spin direction opposite to a spin direction of the top third ferromagnetic thin film structure from near to far from the substrate; a top of the top fixed layer thin film structure is composed of an antiferromagnetic thin film structure for spin pinning; a material of the anti-parallel coupling thin film structure uses any one of metal ruthenium or metal iridium; the oxide coupling thin film structure is composed of any one of magnesium oxide containing, in addition to boron element, any one element of iron and cobalt and having a thickness greater than that of magnesium oxide of the tunneling layer, an oxide of iron, and an oxide containing iron and cobalt; and the antiferromagnetic thin film structure contains at least any one antiferromagnet of a manganese platinum alloy or a manganese iridium alloy.

8. A method for manufacturing a magnetic memory chip of a magnetic tunnel junction with double fixed layers prepared on the basis of the magnetic tunnel junction with double fixed layers according to claim 2, comprising the steps of:
preparing a peripheral circuit of the magnetic memory chip on the substrate;
performing preparation of a bottom electrode of the magnetic tunnel junction on a metal connection layer of the peripheral circuit;
preparing a connection layer between the bottom electrode and the bottom fixed layer thin film structure;
preparing the bottom first ferromagnetic thin film structure, the bottom first anti-parallel coupling thin film structure, the bottom second ferromagnetic thin film structure, the bottom second anti-parallel coupling thin film structure, and the bottom third ferromagnetic thin film structure of the bottom fixed layer thin film structure;
preparing the bottom tunneling layer oxide thin film structure;
preparing the free layer thin film structure;
preparing the top tunneling layer oxide thin film structure;
preparing the top fixed layer thin film structure;
preparing a top cover protective layer;
patterning a thin film to form a device of the magnetic memory chip; and
performing connection and packaging of the device to form a chip.

9. The method for manufacturing a magnetic memory chip of a magnetic tunnel junction with double fixed layers according to claim 8, characterized in that any of the steps of preparing the top fixed layer thin film structure, preparing a top cover protective layer, and patterning a thin film to form a device of the magnetic memory chip is followed by a step of returning to an external field-free environment after being magnetized by a magnetic field of not less than 1 tesla.
